(19) United States
(12) Patent Application Publication
(10) Pub. No.: US 2014/0363942 A1
(43) Pub. Date: Dec. 11, 2014

(54) Method for forming a low resistivity tungsten silicide layer for metal gate stack applications

(71) Applicant: Intermolecular Inc., San Jose, CA (US)

(72) Inventors: Zhendong Hong, San Jose, CA (US); Ashish Bodke, San Jose (CA); Susie Tzeng, San Jose (CA)

(21) Appl. No.: 13/915,324

(22) Filed: Jun. 11, 2013

(51) Int. Cl. H01L 21/28; H01L 29/66

(52) U.S. Cl. CPC H01L 21/28229; H01L 29/66477
USPC 438/287; 438/591

(57) ABSTRACT

Tungsten silicide layers can be used in CMOS transistors in which the work function of the tungsten silicide layers can be tuned for use in PMOS and NMOS devices. A co-sputtering approach can be used in which silicon and tungsten are deposited on a high dielectric constant gate dielectric layer. The tungsten silicide layer can be annealed at or above a critical temperature to optimize the resistivity of the tungsten silicide layer. In some embodiments, the concentration of as-deposited tungsten silicide can be between 50 at % silicon to 80 at % silicon. The critical temperatures can be lower at higher silicon concentration, such as 700 C. at 63 at % silicon to 600 C. at 74 at % silicon.

### FIELD OF THE INVENTION

The present invention relates to methods to form a semiconductor device, and more particularly to methods to form devices having tungsten silicide metal gate.

### BACKGROUND OF THE INVENTION

Advances in semiconductor processing have demanded ever-increasing high density with continuous size scaling. This scaling process has led to the adoption of high-k gate dielectrics and metal gate electrodes in metal gate stacks in semiconductor devices.

High-k gate dielectrics can offer a way to scale down the thickness of the gate dielectric with acceptable gate leakage current. The use of high-k gate dielectrics is often accompanied by a metal gate electrode, since thin gate dielectric layers may cause poly depletion, affecting the device operation and performance.

The introduction of metal elements to the device, e.g., in the formation of the metal gate electrode, can impose significant changes to the device fabrication process, including device structure designs to reduce leakage, process chemistry to pattern metallic structures and avoid metal corrosion, and cleaning chemistry to remove metallic-containing residues.

For complementary metal-oxide-semiconductor (CMOS) transistors with metal gates, it is desirable to fabricate PMOS and NMOS transistors having gates of different work functions. For example, current FinFET replacement metal gate integration scheme uses an Al-based metal gate for NMOS and a TiN-based metal gate for PMOS. Besides the fabrication complexity of using two different metals, Al-based metal gate can have high resistivity, poor thermal stability, and potentially requiring metal cladding.

Therefore, there is a need for methods to form metal gate transistors devices having similar process flows and/or a same metal in the metal gates with a first work function for a PMOS device and a second work function for an NMOS device.

### SUMMARY OF THE DESCRIPTION

In some embodiments, methods, and devices fabricated from the methods, are provided to incorporate tungsten silicide to a metal gate stack. Tungsten silicide can exhibit high electrical conductivity, which can eliminate the need for a gate electrode, as in the case of low conductivity gate metal layer.

In some embodiments, methods, and devices fabricated from the methods, are provided to form a metal gate stack including a tungsten silicide layer on a gate dielectric layer. The tungsten silicide layer can be formed by a deposition process, such as by physical vapor deposition, followed by a high temperature anneal to reduce the resistivity. The high temperature anneal can be specifically performed for the completion of tungsten silicide formation, or can occur due to a subsequent high temperature process.

In some embodiments, methods, and devices fabricated from the methods, are provided to form a tungsten silicide layer having tungsten and silicon concentrations in a vicinity of stoichiometry concentrations of WSi₂, followed by an anneal at temperatures greater than a critical temperature, which can be the temperature where a change in the rate of change of resistivity over temperature of the deposited layer occurs. The concentration of tungsten silicide can be between 50 at % silicon to 80 at % silicon. The critical temperatures can be higher at higher silicon concentration, such as 800 C. at 63 at % silicon to 600 C. at 74 at % silicon.

In some embodiments, the methods can further include determining the critical temperature of the as-deposited tungsten silicide layer. The determination can include table look-up determination, e.g., obtaining the critical temperature based on a table of critical temperatures versus silicon concentration. The determination can include experimental determination, e.g., a series of experiments can be performed at different anneal temperatures to determine the critical temperature at which the resistivity of the annealed tungsten silicide is minimum.

In some embodiments, multiple gate metal stacks can be formed with different concentrations of tungsten silicide in the tungsten silicide layers. The critical temperature for the gate metal stacks can be the highest critical temperatures among the different tungsten silicide layers, leading to minimum resistivity for all metal gate stacks. For advanced semiconductor devices, work functions can be tuned separately for NMOS and PMOS devices, thus can require different materials which exhibit different work function with the gate dielectric. Further, single conducting layer can be used to replace gate metal and gate electrode to meet the need of advanced device scaling.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIGS. 1A-1B illustrate semiconductor device configurations according to some embodiments.

FIG. 2 illustrates a schematic representation of transistor devices incorporating tungsten silicide in a gate stack according to some embodiments.

FIGS. 3A-3B illustrate semiconductor device configurations incorporating tungsten silicide in gate stacks according to some embodiments.

FIG. 4 illustrates an example of a finFET device according to some embodiments.

FIG. 5 illustrates a physical vapor deposition (PVD) system according to some embodiments.

FIGS. 6A-6B illustrate resistivity values of tungsten silicide layers having different silicon percentages according to some embodiments.

FIGS. 7A-7B illustrate crystallography properties of tungsten silicide layers according to some embodiments.

FIGS. 8A-8B illustrate variations of resistivity of tungsten silicide layers with respect to annealing temperatures according to some embodiments.

FIG. 9 illustrates a flow chart for forming a tungsten silicide layer according to some embodiments.

FIG. 10 illustrates a flow chart for forming a CMOS device having tungsten silicide layers according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

In some embodiments, methods, and devices fabricated from the methods, are provided to incorporate tungsten silicide to a metal gate stack. Tungsten silicide can exhibit high electrical conductivity, which can eliminate the need for a gate electrode, as in the case of low conductivity gate metal layer.

In some embodiments, methods, and devices fabricated from the methods, are provided to form a metal gate stack including a tungsten silicide layer on a gate dielectric layer. The tungsten silicide layer can be formed by a deposition process, such as by physical vapor deposition, followed by a high temperature anneal to reduce the resistivity. The high temperature anneal can be specifically performed for the completion of tungsten silicide formation, or can occur due to a subsequent high temperature process.

There can be a critical temperature that when annealed across this temperature, the rate of change of the resistivity of the tungsten silicide layer over temperature changes observably or substantially. In other words, the slope of the resistivity over temperature can experience a change at the critical temperature. For example, if the tungsten silicide film is annealed below this temperature, the resistivity can steadily decrease with higher temperatures, but when annealed at higher than this temperature, the resistivity remains substantially constant. Alternatively, if the tungsten silicide film is annealed below this temperature, the resistivity can slowly decrease, slowly increase, or remain constant with higher temperatures, but when annealed at higher than this temperature, the resistivity decreases with a high rate.

In some embodiments, methods, and devices fabricated from the methods, are provided to form a tungsten silicide layer having tungsten and silicon concentrations in a vicinity of stoichiometry concentrations of WSi₂, followed by an anneal at temperatures greater than a critical temperature, which can be the temperature where a change in the rate of change of resistivity over temperature of the deposited layer occurs. The concentration of tungsten silicide can be between 50 at % silicon to 80 at % silicon. The critical temperatures can be higher at higher silicon concentration, such as 800 C. at 63 at % silicon to 600 C. at 74 at % silicon.

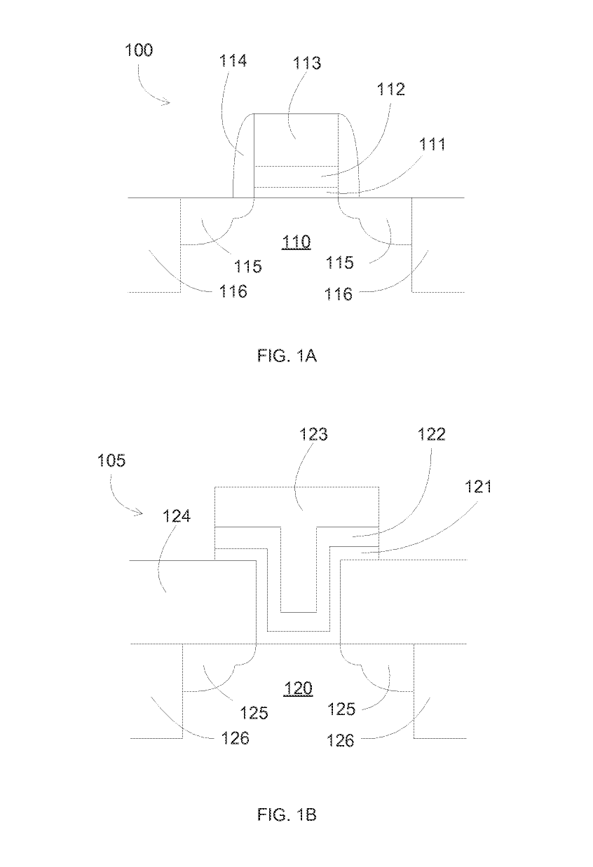

FIGS. 1A-1B illustrate semiconductor device configurations according to some embodiments. In FIG. 1A, a transistor structure 100 is formed on a substrate 110. A gate stack can be fabricated on the substrate 110, including a gate dielectric layer 111, a gate layer 112 over the gate dielectric layer 111, and a gate conductor layer 113 over the gate layer 112. The gate conductor 113 can include high conductivity materials, such as tungsten or aluminum, to improve the conduction of the gate stack. The device 100 is isolated from other devices by isolation regions 116. The device 100 also includes spacers 114 and source and drain regions 115.

FIG. 1B shows a replacement gate configuration for a transistor device. The device 105 can be fabricated on a substrate 120, including a gate dielectric layer 121, a gate layer 122 over the gate dielectric layer 121, and a gate conductor layer 123 over the gate layer 122. The gate structure can be fabricated in an opening of a protective layer 124.

In some embodiments, methods, and devices fabricated from the methods, are provided to form a metal gate stack including a tungsten silicide layer on a gate dielectric layer. The tungsten silicide layer can be formed by a deposition process, such as by physical vapor deposition, followed by a high temperature anneal to reduce the resistivity. The high temperature anneal can be specifically performed for the completion of tungsten silicide formation, or can occur due to a subsequent high temperature process.

Further, high electrical conductivity of tungsten silicide can eliminate the need for a gate conductor. The single conducting gate electrode can be used to meet the need of advanced device scaling. For advanced technology nodes, the total thickness of metal gate and fill metal can be required to be less than 5 nm for a gate length less than 20 nm, so a single layer metal gate structure that can have tunable work function value to work either as a NMOS or a PMOS device can be advantageous.

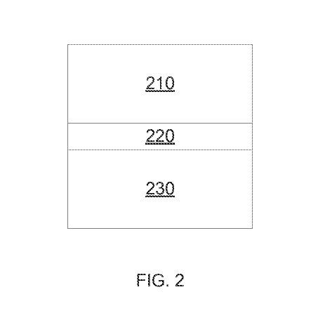

FIG. 2 illustrates a schematic representation of transistor devices incorporating tungsten silicide in a gate stack according to some embodiments. In FIG. 2, a transistor devices having a tungsten silicide layer 210 is disposed on a dielectric layer 220, such as a high dielectric constant layer, on a substrate 230, such as a silicon substrate.

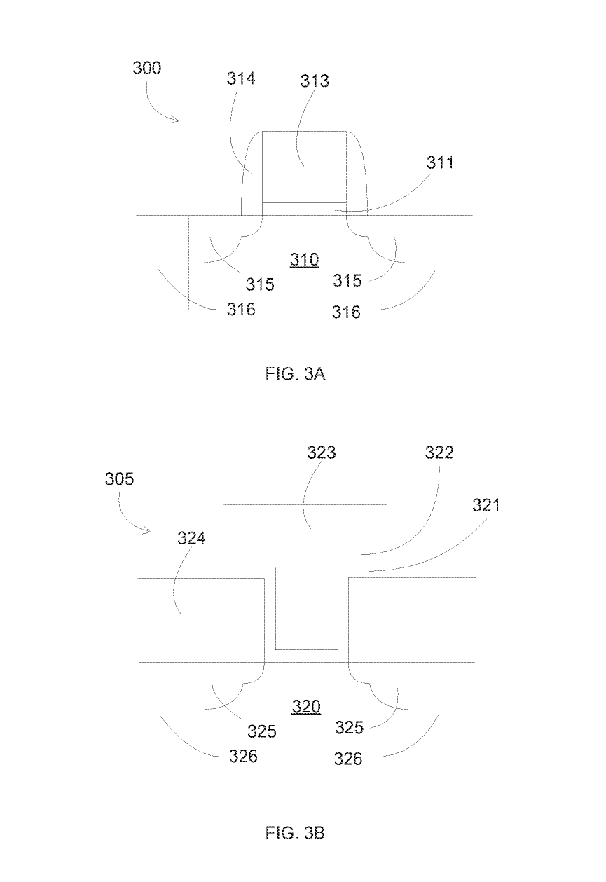

FIGS. 3A-3B illustrate semiconductor device configurations incorporating tungsten silicide in gate stacks according to some embodiments. In FIG. 3A, a transistor structure 300 is formed on a substrate 310, which can be single crystal silicon, although other substrates can be used, such as glass substrates, silicon-germanium substrates, or GaAs substrates. A gate stack can be fabricated on the substrate 310, including a gate dielectric layer 311, a gate layer 313 over the gate dielectric layer 311. The gate layer 313 can include tungsten silicide, with a silicon concentration optimized to achieve a desired work function, for example, to achieve a threshold voltage for the transistor device. The tungsten silicide can have high conductivity, thus can also function as a gate conductor, eliminating the need for a separate gate conductor. The device 300 is isolated from other devices by isolation regions 316, such as shallow trench isolation or local oxidation of silicon (LOCOS) isolation. The device 300 also includes spacers 314 and source and drain regions 315. FIG. 3A shows a metal-oxide-semiconductor field effect transistor (MOSFET) structure, but the invention is not so limited, and can include any transistor structure, such as bipolar transistors, fin transistors or double gate transistors. Further, silicide layers can be included, such as TiSi₂, CoSi₂, NiSi, or NiPtSi, for the source and drain regions 315, which can form low contact resistance with the source and drain regions. Other components can be included, such as n or p well regions, depending on the type of the semiconductor devices. For example, NMOS devices can be fabricated directly on a p-type substrate, and PMOS devices can be fabricated in an n-well on the p-type substrate. For n-type substrate, NMOS devices can be fabricated in a p-well, while PMOS devices can be fabricated directly on the n-type substrate. Alternatively, for a twin well process, NMOS devices can be fabricated in a p-well, while PMOS devices can be fabricated in a p-well, with both n-well and p-well formed in the substrate. The transistor device 300 can be incorporated in integrated circuits, further comprising interconnects for connecting multiples devices.

FIG. 3B shows a replacement gate configuration for a transistor device. The device 305 can be fabricated on a substrate 320, including a gate dielectric layer 321, a gate layer 322 over the gate dielectric layer 321. The gate layer 322 can include tungsten silicide, with a silicon concentration optimized to achieve a desired work function, for example, to achieve a threshold voltage for the transistor device. The tungsten silicide can have high conductivity, thus can also function as a gate conductor. The gate structure can be fabricated in an opening of a protective layer 324. The device shown is an exemplary planar device configuration, and other device configurations are also within the scope of the present invention, such as tri-gate transistor configurations, fin-FET configurations, or different types of transistors or devices. The metal gate device 305 can be incorporated in integrated circuits, further comprising interconnects for connecting multiples devices.

In some embodiments, the tungsten silicide can be used in a gate stack for finFET devices. The tungsten silicide layer can functioned as a matching work function layer, together with having excellent thermal stability and high conductivity as a gate electrode.

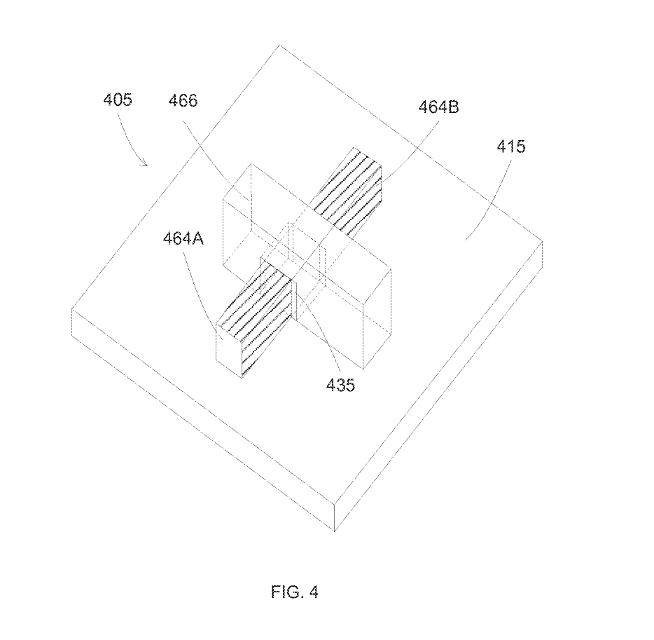

FIG. 4 illustrates an example of a finFET device according to some embodiments. A finFET device 405 having a semiconductor body having a fin shape formed on a substrate 415. Source/drain regions 464A/464B can be formed at opposite ends of the semiconductor body. A gate dielectric 435 can be formed on a portion between the source and drain regions, which becomes a channel region of the finFET device. The gate dielectric 435 can include a high dielectric constant material, such as HfO₂, Al₂O₃, or ZrO₂. A gate layer 466 can be formed on the gate dielectric 425. The gate layer 466 can include tungsten silicide, with a silicon concentration optimized to achieve a desired work function, for example, to achieve a threshold voltage for the transistor device. The tungsten silicide can have high conductivity, thus can also function as a gate conductor. The source/drain regions can be doped, for example, with p-type or n-type dopants to form p-type or n-type devices. The doping of the source/drain regions can be accomplished by doping the whole semiconductor body, using the gate electrode to act as a mask to prevent the channel region from being doped. As shown, the gate dielectric and the gate electrode surround the channel on two sides, forming a double-gate finFET device.

In some embodiments, the tungsten silicide layer can be sputter deposited from one or more targets onto the same substrate. The process may be in Ar. For example, the tungsten silicide layer can be deposited by a combination of tungsten and silicon precursors, such as utilizing a tungsten target in combination with a silicon target in a physical vapor deposition process. The tungsten silicide layer can be deposited by a combination of tungsten silicide and silicon precursors, such as utilizing a tungsten silicide target (e.g., WSiₓ, with x between 0 and 2) in combination with a silicon target in a physical vapor deposition process. Other configurations can be used, such as a tungsten target is used with a tungsten silicide target.

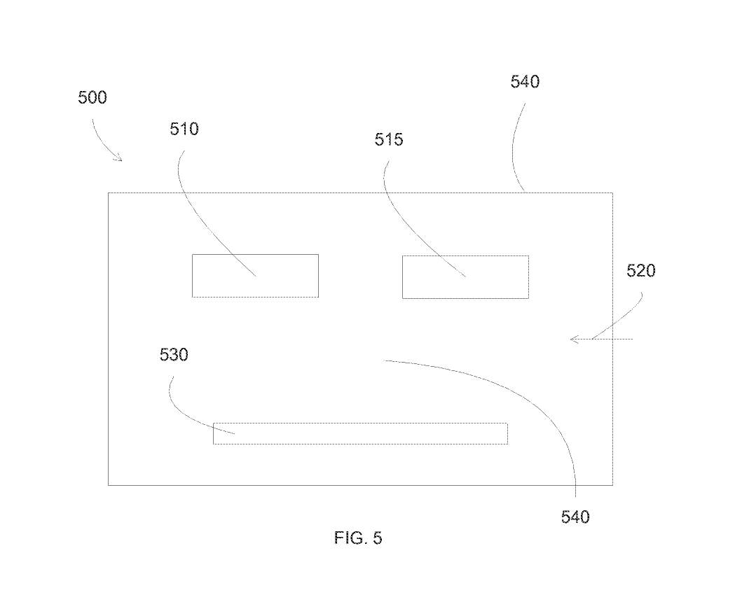

FIG. 5 illustrates a physical vapor deposition (PVD) system according to some embodiments. A PVD system, also commonly called sputter system or sputter deposition system, 500 includes a housing that defines, or encloses, a processing chamber 540, a substrate 530, two target assemblies 510 and 515, and reactive species delivered from an outside source 520. During deposition, the target is bombarded with argon ions, which releases sputtered particles toward the substrate 530. The sputter system 500 can perform blanket deposition on the substrate 530, forming a deposited layer that covers the whole substrate, e.g., the area of the substrate that can be reached by the sputtered particles generated from the target assembly 510. The target assemblies 510 and 515 can include silicon and tungsten, respectively.

The sputter deposition system 500 can include other components, such as a substrate support for supporting the substrate. The substrate support can include a vacuum chuck, electrostatic chuck, or other known mechanisms. The substrate support can be capable of rotating around an axis thereof that is perpendicular to the surface of the substrate. In addition, the substrate support may move in a vertical direction or in a planar direction. It should be appreciated that the rotation and movement in the vertical direction or planar direction may be achieved through known drive mechanisms which include magnetic drives, linear drives, worm screws, lead screws, a differentially pumped rotary feed through drive, etc.

In some embodiments, the substrate support includes an electrode which is connected to a power supply, for example, to provide a RF or DC bias to the substrate, or to provide a plasma environment in the process housing 540. The target assemblies 510 and 515 can each include an electrode which is connected to a power supply to generate a plasma in the process housing. The target assemblies 510 and 515 are each preferably oriented towards the substrate 530.

The sputter deposition system 500 can also include a power supply coupled to the target electrodes. The power supply provides power to the electrodes, causing material to be, at least in some embodiments, sputtered from the target. During sputtering, inert gases, such as argon or krypton, may be introduced into the processing chamber 540 through the gas inlet 520. In embodiments in which reactive sputtering is used, reactive gases may also be introduced, such as oxygen and/or nitrogen, which interact with particles ejected from the targets to form oxides, nitrides, and/or oxynitrides on the substrate.

The sputter deposition system 500 can also include a control system (not shown) having, for example, a processor and a memory, which is in operable communication with the other components and configured to control the operation thereof in order to perform the methods described herein.

In some embodiments, the interface at the tungsten silicide and the gate dielectric can be optimized, for example, to minimize damage to the gate dielectric during the first deposition layer of the nanolaminate sequence or to improve the performance of the metal gate stack. For example, since tungsten can be deposited using a DC sputtering process, which can generate plasma damage to the gate dielectric during first few deposition cycles, the nanolaminate deposition sequence can start with the RF silicon sputter deposition process. Further, the thickness or the number of silicon deposition layers at the interface can be optimized to reduce the plasma damage. For example, a silicon layer can be deposited first in the sequence of tungsten-silicon nanolaminate sequence. Also, the thickness of the first silicon layer can be higher than subsequent silicon layer, or multiple silicon layers can be deposited, e.g., to shield the gate dielectric from the subsequent tungsten process conditions. To achieve a desired composition tungsten-silicon ratio, the deposition of the subsequent tungsten layers can be adjusted accordingly. Due to the mild nature of the RF silicon deposition process, there can be minimal impact of the tungsten silicide formation to underlying high-k dielectrics.

The resistivity of tungsten silicide layer can be high (for example, greater than 400 μΩ-cm, and even higher with increasing percentage of silicon), which doesn't meet integration requirements. In some embodiments, thermal treatments are provided to lower the resistance state for tungsten silicide layers. The crystalline phases can also be controlled to optimize the tungsten silicide properties.

In some embodiments, tungsten and silicon can be co-sputtered to form tungsten silicide thin films, followed by annealing. There can be critical temperatures for the thermal treatment to optimize the sheet resistance of tungsten silicide. The critical temperatures can decrease with increasing silicon percentage in tungsten silicide.

The resistivity of tungsten silicide can vary depending on the percentage of silicon in the silicide layers, together with subsequent thermal treatments. For example, as-deposited tungsten silicide layers can have low resistivity at low silicon percentages, and higher resistivity at higher silicon percentages. After annealing, the low resistance tungsten silicide at low silicon percentages can significantly increase, while the high resistance tungsten silicide at high silicon percentages can remain high. Thus a middle range of silicon percentage can be used to optimize the resistivity of tungsten silicide.

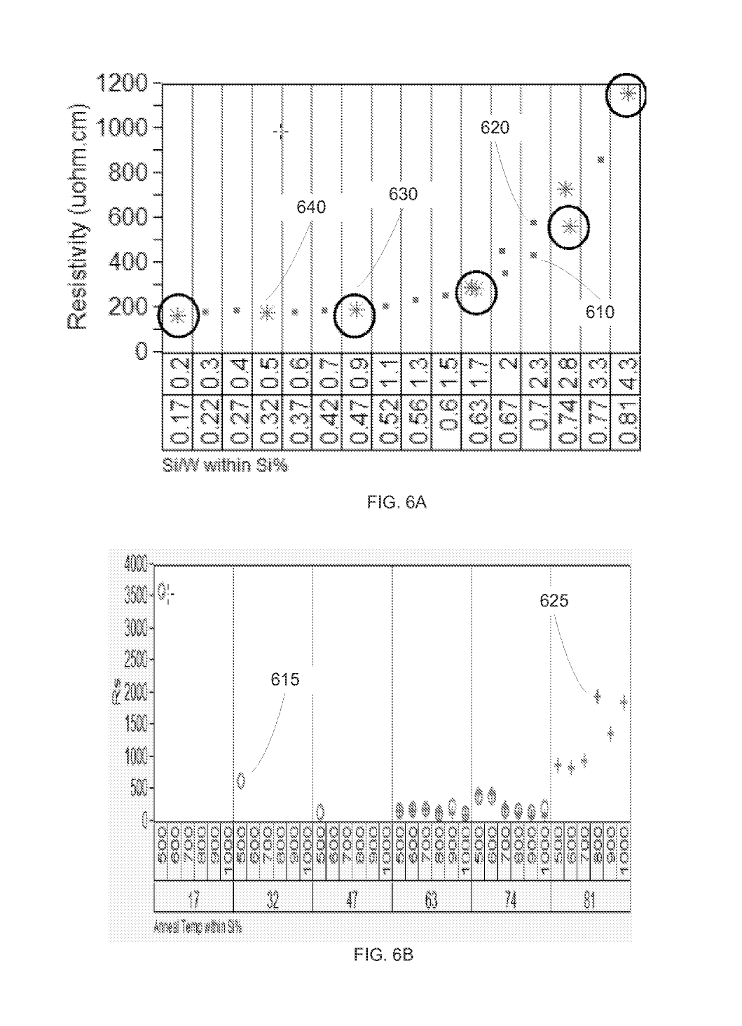

FIGS. 6A-6B illustrate resistivity values of tungsten silicide layers having different silicon percentages according to some embodiments. In FIG. 6A, the resistivity values of as-deposited tungsten silicide layers are shown as a function of silicon percentages in the silicide layers. In addition, different target configurations can be used to form the tungsten silicide layers. For example, tungsten and silicon targets can be co-sputtered to form the silicide layers 610. Tungsten silicide and silicon targets can be co-sputtered to form the silicide layers 620. At high silicon percentages, e.g., greater than about 65 at % of silicon, tungsten silicides sputtered from tungsten and silicon targets can show lower resistivity as compared to tungsten silicides sputtered from tungsten silicide and silicon targets. Selected compositions 640 can be used to evaluate high temperature annealing effect. Also selected compositions 630 can be used to evaluate electrical properties.

The resistivity of as-deposited tungsten silicide can vary, depending on the composition of the tungsten silicide. At less than about 50 at %, the resistivity of as-deposited tungsten silicide can be reasonable, e.g., about 200 μΩ-cm. The resistivity of as-deposited tungsten silicide can increase significantly above 50 at % silicon, for example, to about 300 μΩ-cm at 63 at % silicon, to about 600 μΩ-cm at 74 at % silicon, and to about 1200 μΩ-cm at 81 at % silicon.

In FIG. 6B, the resistivity values of tungsten silicide layers after being annealed are shown as a function of silicon percentages in the silicide layers. In addition, different target configurations can be used to form the tungsten silicide layers. For example, tungsten and silicon targets can be co-sputtered to form the silicide layers 615. Tungsten silicide and silicon targets can be co-sputtered to form the silicide layers 625. At low and high silicon percentages, e.g., less than 47 at % and greater than about 74 at % of silicon, annealed tungsten silicide layers can have high resistivity. At middle silicon percentages, e.g., between 47 and 74 at %, the annealed tungsten silicide layers can have low resistivity.

The resistivity of annealed tungsten silicide can vary, depending on the composition of the tungsten silicide. At less than about 40 at %, the resistivity of annealed tungsten silicide can be high, e.g., above 500 μΩ-cm. The resistivity of annealed tungsten silicide can increase significantly above 75 at % silicon, for example, to above 500 μΩ-cm at 81 at % silicon.

In some embodiments, tungsten silicide layers having silicon percentages in a middle range between 45 and 80 at % can be deposited. The middle range of silicon percentage can offer tungsten silicide layers with low resistivity, before and after any subsequent high temperature processes.

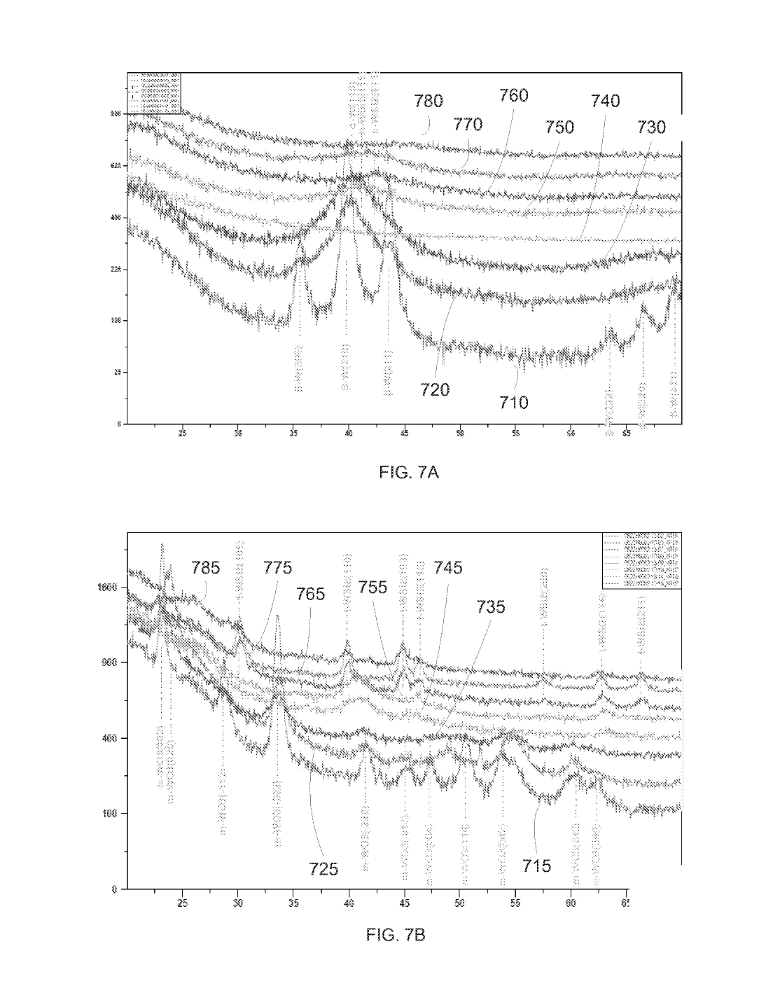

FIGS. 7A-7B illustrate crystallographic properties of tungsten silicide layers according to some embodiments. In FIG. 7A, crystalline phases of as-deposited tungsten silicide layers, as characterized from x-ray diffraction (XRD) measurements, are shown for different silicon percentages, e.g., for co-sputtering from tungsten and silicon from 17 at % (curve 710), 27 at % (curve 720), 42 at % (curve 730), 56 at % (curve 740), 63 at % (curve 750), 74 at % (curve 760); and for co-sputtering from tungsten silicide and silicon from 63 at % (curve 770) to 81 at % (curve 780) of silicon. At low silicon percentages, e.g., at 17 and 27 at % of silicon, the layers have tungsten phases, which can explain the low resistivity of as deposited tungsten silicide layer with low silicon percentages. For example, at 17 at % silicon, the layers has tungsten beta phases of (200), (210), and (211). At 27 at %, the layers has cubic tungsten (110) phase. At higher silicon percentages, e.g., 42, 63, and 74 at % of silicon, the layers have tungsten disilicide phases, which can explain the higher, but still low resistivity, of tungsten silicide layers. For example, at 42 at % silicon, the layer has hexagonal tungsten disilicide (211) phase. At 74 at %, the layer has cubic tungsten disilicide (511) phases. At very high silicon percentages, e.g., 81 at % of silicon, the layers become amorphous, which results in much higher resistivity.

In FIG. 7B, crystalline phases of annealed tungsten silicide layers, as characterized from x-ray diffraction (XRD) measurements, are shown for the same silicon percentages, e.g., for co-sputtering from tungsten and silicon from 17 at % (curve 715), 27 at % (curve 725), 42 at % (curve 735), 56 at % (curve 745), 63 at % (curve 755), 74 at % (curve 765); and for co-sputtering from tungsten silicide and silicon from 63 at % (curve 775) to 81 at % (curve 785) of silicon. At low silicon percentages, e.g., lower than 47 at % of silicon, the annealed layers exhibit tungsten oxide phases, e.g., monoclinic WO₃ phases, which can explain the high resistivity of the annealed layers with low silicon percentages. For example, at 17 at % silicon, the layers have monoclinic WO₃ phases of (002), (020), (112), (202), (222), (312), (004), (114), (042), (242), and (340). This data indicates that the annealed layers have incorporated a substantial amount of oxygen from the ambient, thus oxidizing tungsten phases to tungsten oxide phases.

At higher silicon percentages, e.g., in a middle range at 63 and 74 at %, the annealed layers exhibit tungsten silicide phases, e.g., tetragonal WSi₂ phases, which can explain the low resistivity of the annealed layers with silicon percentages in the middle rages between 47 and 81 at %. For example, at 63 and 74 at % silicon, and from two different co-sputtering approaches of tungsten+silicon and tungsten silicide+silicon, the layers have tetragonal WSi₂ phases of (201), (210), (103), (112), (200), (114), and (211).

At highest silicon percentages, e.g., 81 at % and higher, the annealed layers remains largely amorphous, for both co-sputtering approaches of tungsten+silicon and tungsten silicide+silicon. The behaviors of the tungsten silicide layers are similar for two different co-sputtering approaches of tungsten+silicon and tungsten silicide+silicon.

At low silicon percentages, the tungsten silicide layers exhibit some tungsten crystallinity, which can be oxidized under a high temperature anneal to show high resistivity. Thus the post-anneal resistivity does not correlate with the initial as-deposited resistivity. Low silicon concentration can lead to high post-anneal resistivity, even with low initial as-deposited resistivity. For example, at low concentration of silicon, e.g., less than 50 at % silicon, the resistivity of post-anneal tungsten silicide can increase significantly, such as beyond the limit of measurement at 17 at % silicon to about 700 μΩ-cm at 32 at % silicon. The high post-annealed resistivity can be attributed to the oxidation of tungsten, e.g., WO₃ formation, for example, due to the reaction of tungsten with oxygen in the ambient.

At high silicon percentages, the tungsten silicide layers is amorphous, and remain amorphous after a high temperature anneal. The resistivity can be high for as-deposit or annealed tungsten silicide layers with high percentage of silicon. For example, at above 80 at % silicon, the post-annealed resistivity becomes high at practical anneal temperature ranges. At 81 at % silicon, the post-annealed resistivity can be higher than 1000 μΩ-cm in the temperature range between 500 and 1000 C.

In the middle range of silicon percentage, e.g., between 50 and 80 at % of silicon, the resistivity of the tungsten silicide layers can also vary, depending on the temperature of the annealing. In general, the post-anneal resistivity decreases with increasing concentration of silicon.

At higher than 50 at % silicon, the post-anneal resistivity can decrease to below 200 μΩ-cm. There can be a critical temperature that across this temperature, the slope of the resistivity v. temperature changes observably or substantially. For example, the rate of change of resistivity can change more than 5 or 10 μΩ-cm per 100 C. in absolute value. The critical temperatures can also decrease with increasing silicon concentrations. For example, at 63 at % silicon, the critical temperature can be about 800 C. At 74 at % silicon, the critical temperature can be about 600 C. The low post-annealed resistivity can be attributed to the formation of high conductivity tungsten silicide phases, e.g., WSi₂ formation, due to the proximity of silicon concentration range with WSi₂.

In some embodiments, methods, and devices fabricated from the methods, are provided to form a tungsten silicide layer tungsten and silicon concentrations in a vicinity of stoichiometry concentrations of WSi₂, followed by an anneal at temperatures greater than a critical temperature. The concentration of tungsten silicide can be between 50 at % silicon to 80 at % silicon. The critical temperatures can be higher at higher silicon concentration, such as 800 C. at 63 at % silicon to 700 C. at 74 at % silicon.

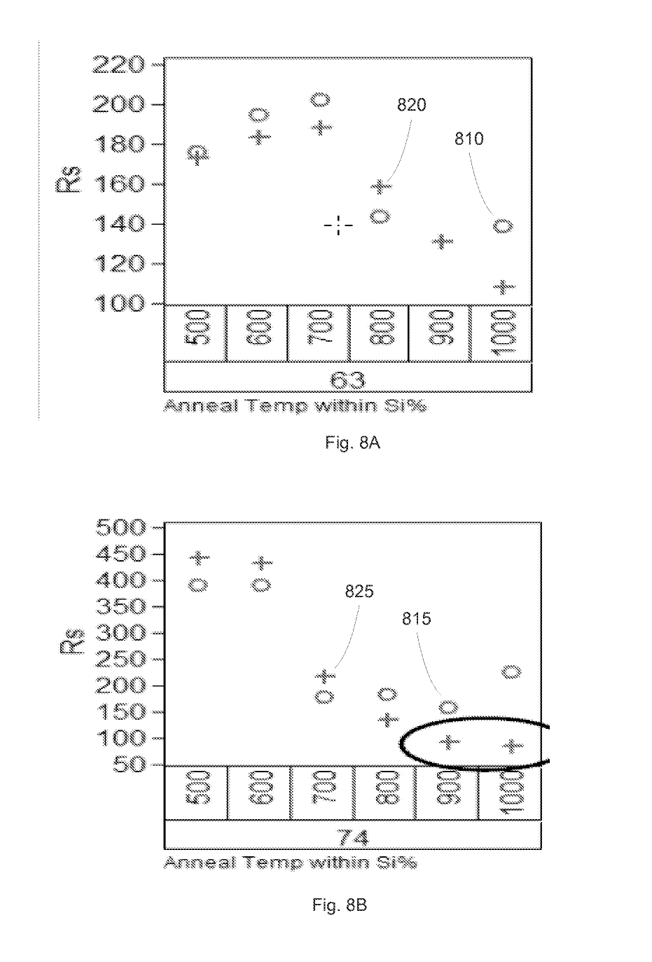

FIGS. 8A-8B illustrate variations of resistivity of tungsten silicide layers with respect to annealing temperatures according to some embodiments. In FIG. 8A, the resistivity of tungsten silicide layers having 63 at % silicon is shown for annealing temperatures between 500 and 1000 C. Also shown are two different co-sputtering approaches of tungsten+silicon (810) and tungsten silicide+silicon (820). As can be seen, the resistivity of the silicide layers can be lowered at higher than 700 C. annealing temperature. At 800 C. or higher, the resistivity of the tungsten silicide layers can be lowered to 140 μΩ-cm. The critical temperature for tungsten silicide layer having 63 at % silicon concentration can be about 700 C. Below this temperature, the rate of change of resistivity is about 10 μΩ-cm per 100 C. Above this temperature, the rate of change of resistivity is about −20 μΩ-cm per 100 C. The rate of change of the resistivity can change substantially across the critical temperature, for example, from 10 μΩ-cm per 100 C. to −20 μΩ-cm per 100 C., for about 30 μΩ-cm per 100 C.

In FIG. 8B, the resistivity of tungsten silicide layers having 74 at % silicon is shown for annealing temperatures between 500 and 1000 C. Also shown are two different co-sputtering approaches of tungsten+silicon (815) and tungsten silicide+silicon (825). As can be seen, the resistivity of the silicide layers can be lowered at higher than 600 C. annealing temperature. At 700 C. or higher, the resistivity of the tungsten silicide layers can be lowered to 150 μΩ-cm. The critical temperature for tungsten silicide layer having 74 at % silicon concentration can be about 600 C. Below this temperature, the rate of change of resistivity is about 0 μΩ-cm per 100 C. Across this temperature, the rate of change of resistivity is about −200 μΩ-cm per 100 C. between 600 and 700 C. Above this range, the rate of change of resistivity is about 0 to −50 μΩ-cm per 100 C. The rate of change of the resistivity can change substantially across the critical temperature, for example, from 0 μΩ-cm per 100 C. to −200 μΩ-cm per 100 C., for about 200 μΩ-cm per 100 C. across the critical temperature of 600 C.

In addition, electrical tests have been performed. The electrical data further confirms that this additional anneal lowers gate resistance while maintaining effective work function of the gate stack.

In some embodiments, the methods can further include determining the critical temperature of the as-deposited tungsten silicide layer. The determination can include table look-up determination, e.g., obtaining the critical temperature based on a table of critical temperatures versus silicon concentration. The determination can include experimental determination, e.g., a series of experiments can be performed at different anneal temperatures to determine the critical temperature at which the resistivity of the annealed tungsten silicide is minimum.

In some embodiments, the tungsten silicide layer can be deposited by a combination of tungsten and silicon precursors, such as utilizing a tungsten target in combination with a silicon target in a physical vapor deposition process. The tungsten silicide layer can be deposited by a combination of tungsten silicide and silicon precursors, such as utilizing a tungsten silicide target (e.g., WSiₓ, with x between 0 and 2) in combination with a silicon target in a physical vapor deposition process. Other configurations can be used, such as a tungsten target is used with a tungsten silicide target.

In some embodiments, multiple gate metal stacks can be formed with different concentrations of tungsten silicide in the tungsten silicide layers. The critical temperature for the gate metal stacks can be the highest critical temperatures among the different tungsten silicide layers, leading to minimum resistivity for all metal gate stacks. For advanced semiconductor devices, work functions can be tuned separately for NMOS and PMOS devices, thus can require different materials which exhibit different work function with the gate dielectric. Further, single conducting layer can be used to replace gate metal and gate electrode to meet the need of advanced device scaling.

In some embodiments, methods, and devices fabricated from the methods, are provided to incorporate tungsten silicide to a metal gate stack. Tungsten silicide can exhibit high electrical conductivity, which can eliminate the need for a gate electrode, as in the case of low conductivity gate metal layer.

In some embodiments, methods, and devices fabricated from the methods, are provided to form a metal gate stack including a tungsten silicide layer on a gate dielectric layer. The tungsten silicide layer can be formed by a deposition process, such as by physical vapor deposition, followed by a high temperature anneal to reduce the resistivity. The high temperature anneal can be specifically performed for the completion of tungsten silicide formation, or can occur due to a subsequent high temperature process.

In some embodiments, the tungsten silicide layer can be used in a gate stack for finFET devices. The tungsten silicide layer can functioned as a matching work function layer, together with having excellent thermal stability and high conductivity as a gate electrode.

In some embodiments, methods to form gate stack including tungsten silicide layer are disclosed. The tungsten silicide layer can be formed by a co-sputtering process, followed by an anneal at or above a critical temperature to obtain a low resistivity tungsten silicide layer.

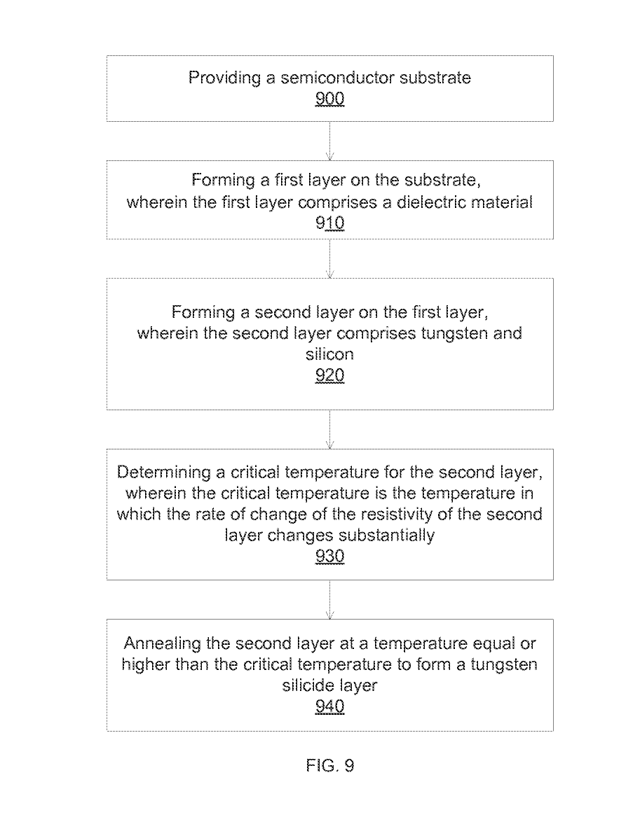

FIG. 9 illustrates a flow chart for forming a tungsten silicide layer according to some embodiments. After forming a dielectric layer on a substrate, such as a high dielectric constant dielectric layer, tungsten and silicon can be co-sputtered on the dielectric layer. The substrate then can be annealed to form a tungsten silicide layer.

In operation 900, a substrate is provided. The substrate can be a semiconductor substrate, such as a silicon substrate, a germanium substrate, or a silicon-germanium substrate. Other substrates can also be used, such as a GaAs substrate, or a substrate having a semiconductor layer formed thereon.

In operation 910, a dielectric layer can be formed on the substrate. The dielectric layer can include a high dielectric constant material, such as HfO₂, Al₂O₃, or ZrO₂. The thickness of the dielectric layer can be less than or equal to about 10 nm, or can be less than or equal to about 5 nm.

In operation 920, a layer including tungsten and silicon is formed on the dielectric layer. The thickness of the tungsten and silicon layer can be less than 10 nm or less than 5 nm. Tungsten and silicon can be co-sputtered from one or two targets to form a layer of tungsten and silicon. Different target configurations can be used. For example, the targets can include a tungsten target and a silicon target, or a tungsten silicide target, e.g., a target having tungsten and silicon, and a silicon target.

In some embodiments, the silicon percentage of the layer of tungsten and silicon can be between 50 and 80 at %. Tungsten and silicon can partially form tungsten silicide in the layer.

In operation 930, a critical temperature for the layer of tungsten and silicon can be determined. The critical temperature is the temperature in which the rate of change of the resistivity of the layer changes substantially. The critical temperature can be a function of silicon percentage in the layer of tungsten and silicon. In some embodiments, the critical temperature is smaller for higher silicon percentage for a silicon percentage between 50 and 80 at %. For example, between 50 and 65 at % silicon, the critical temperature can be about 700 C. Between 65 and 75 at % silicon, the critical temperature can be about 600 C. Also between 75 and 80 at % silicon, the critical temperature can be about 600 C. or slightly less, such as 550 C.

In some embodiments, the determination of the critical temperature can be performed separately, for example, as a characterization of the tungsten silicide process.

In operation 940, the substrate is annealed at a temperature equal or higher than the critical temperature. Tungsten and silicon can form tungsten silicide. Other processes can be included, for example, source and drain regions can be formed on the substrate before forming the first layer. Metal interconnect can be formed after forming the tungsten silicide layer.

In some embodiments, methods to form CMOS devices using gate stacks including tungsten silicide layers having different work function, e.g., through different concentration of silicon, are disclosed. The tungsten silicide layer can be formed by a co-sputtering process, which can allow varying the concentration of tungsten and silicon in the tungsten silicide layers.

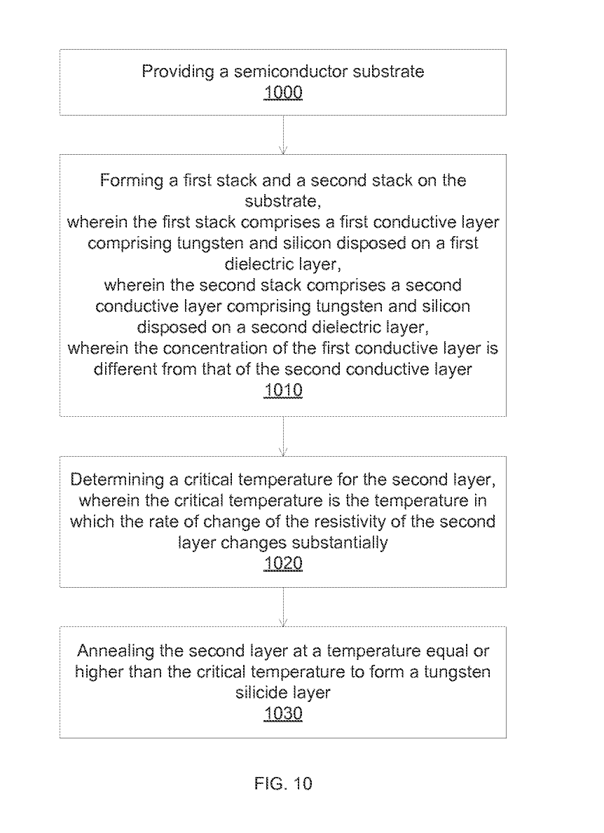

FIG. 10 illustrates a flow chart for forming a CMOS device having tungsten silicide layers according to some embodiments. In operation 1000, a substrate is provided. In operation 1010, a first gate stack and a second gate stack are formed on the substrate. The first gate stack can include a first conductive layer having tungsten and silicon disposed on a first dielectric layer. The second gate stack can include a second conductive layer having tungsten and silicon disposed on a second dielectric layer. The dielectric layer can include a high dielectric constant material, such as HfO₂, Al₂O₃, or ZrO₂. The concentration of the first conductive layer is different from that of the second conductive layer. Other processes can be added, such as forming n-well and p-well in the substrate. Alternatively, the substrate can be p-type, and only n-well can be formed on the p-type substrate. Or the substrate can be n-type, and only p-well can be formed. The first gate stack having a first tungsten silicide layer can be formed on the dielectric layer in the p-well area. A second gate stack having a second tungsten silicide layer can be formed on the dielectric layer in the n-well area. The first and second tungsten silicide layers can have different silicon concentration. The silicon concentrations of the first and second tungsten silicide layers can be selected to optimize the work function of the tungsten silicide layers. In some embodiments, the silicon and tungsten layers can be deposited using a physical vapor deposition process.

In operation 1020, critical temperatures for the layers of tungsten and silicon can be determined. In some embodiments, the determination of the critical temperature can be performed separately, for example, as a characterization of the tungsten silicide process.

In operation 1030, the substrate is annealed at a temperature equal or higher than the critical temperature. Tungsten and silicon can form tungsten silicide. Other processes can be included, for example, source and drain regions can be formed on the substrate before forming the first layer. Metal interconnect can be formed after forming the tungsten silicide layer.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method of forming a film stack, the method comprising:
providing a substrate;
forming a first layer above the substrate,
wherein the first layer comprises a dielectric material;
forming a second layer on the first layer,
wherein the second layer comprises tungsten and silicon;
determining a critical temperature for the second layer,
wherein the critical temperature is a temperature at which a rate of change of second layer resistivity over temperature changes observably; and
annealing the second layer at a temperature higher than the critical temperature.

2. A method as in claim 1 wherein the first layer comprises a high-k material.

3. A method as in claim 1 wherein forming the second layer is performed using a physical vapor deposition process.

4. A method as in claim 1 wherein the second layer is formed by co-sputtering a tungsten target and a silicon target.

5. A method as in claim 1 wherein the second layer is formed by co-sputtering a tungsten silicide target and a silicon target.

6. A method as in claim 1 wherein a silicon concentration in the second layer is between 50 and 80 at %.

7. A method as in claim 1 wherein the critical temperature is above 700 C. for silicon concentrations in the second layer between 50 and 65 at %.

8. A method as in claim 1 wherein the critical temperature is above 600 C. for silicon concentrations in the second layer between 65 and 75 at %.

9. A method as in claim 1 further comprising
forming source and drain regions on the substrate before forming the first layer.

10. A method as in claim 1 further comprising
forming a metal interconnect after forming the second layer.

11. A method of forming a device, the method comprising:
providing a substrate;
forming a first stack and a second stack on the substrate,
wherein the first stack comprises a first conductive layer comprising tungsten and silicon disposed on a first dielectric layer,
wherein the second stack comprises a second conductive layer comprising tungsten and silicon disposed on a second dielectric layer,
wherein a concentration of silicon in the first conductive layer is different from a concentration of silicon in the second conductive layer;
determining critical temperatures for the first and second conductive layers,
wherein each of the critical temperatures is a temperature at which a rate of change of conductive layer resistivity over temperature changes observably; and
annealing the first and second stacks at a temperature above the highest of the determined critical temperatures to form tungsten silicide layers.

12. A method as in claim 14 wherein the first and second dielectric layers each comprise a high-k material.

13. A method as in claim 14 wherein the first and second dielectric layers comprise a single dielectric layer, and wherein the first and second conductive layers are formed on different portions of the single dielectric layer.

14. A method as in claim 14 wherein the second layer is formed by co-sputtering a tungsten target and a silicon target or by co-sputtering a tungsten silicon target and a silicon target.

15. A method as in claim 14 wherein the silicon concentration in the first or second conductive layer is between 50 and 80 at %.

16. A method as in claim 14 further comprising
forming source and drain regions on the substrate before forming the first and second dielectric layers.

17. A method as in claim 14 further comprising
forming a metal interconnect after forming the first conductive layer or the second conductive layer.

18. A method of forming a film stack, the method comprising:
providing a substrate;
forming a first layer above the substrate;
forming a second layer on the first layer;
wherein the second layer comprises tungsten and silicon; and
annealing the second layer at a temperature higher than about 600 C.;
wherein the first layer comprises a dielectric material; and
wherein a silicon concentration in the second layer is between about 50 and about 75 at %.

19. A method as in claim 18 wherein the temperature is above 700 C.; and
wherein the silicon concentration in the second layer is between about 50 and 65 at %.

20. A method as in claim 18 wherein the temperature is lower than about 700 C.;
and wherein the silicon concentration in the second layer is between about 65 and about 75 at %.
